(19) United States
(12) Patent Application Publication
(10) Pub. No.: US 2011/0023784 A1
(43) Pub. Date: Feb. 3, 2011

(54) EVAPORATOR

(76) Inventors: Yusaku Kashiwagi, Yamanashi (JP); Kippei Sugita, Yamanashi (JP)

Correspondence Address: IPUSA, P.L.L.C, 1054 31ST STREET, N.W., Suite 400, Washington, DC, 20007, US

(21) Appl. No.: 12/933,878

(22) PCT Filed: Mar. 11, 2010
(86) PCT No.: PCT/JP2010/054118

§ 371 Date: Sep. 22, 2010

(30) Foreign Application Priority Data
Mar. 13, 2009 (JP) 2009-061587

(51) Int. Cl. H01L 21/469

(52) U.S. Cl. 118/726

(57) ABSTRACT

An evaporator includes a heating part that heats and sublimates a solid source material to generate a source gas; a supplying part that is provided above the heating part and supplies the solid source material to the heating part; a gas introduction part to which a carrier gas that transports the source gas generated in the heating part is introduced; and a gas discharging part that discharges the generated source gas along with the carrier gas. The carrier gas introduced from the gas introduction part flows through the heating part.

### TECHNICAL FIELD

The present invention relates to an evaporator that supplies a source gas along with a carrier gas to a film deposition chamber of a film deposition apparatus.

### BACKGROUND ART

Materials for use in semiconductor devices are now increasing their range from inorganic to organic substances. The organic substances having properties unobtainable from the inorganic materials may make it possible to further optimize production processes and characteristics of semiconductor devices.

Such organic materials include polyimide, which has higher adhesiveness and greater resistance against leakage current, and thus can be used as an insulation layer in semiconductor devices.

As a method of depositing such a polyimide film, there has been known a film deposition method employing vapor deposition polymerization, in which 4,4-Oxydianiline (ODA) and Pyromellitic Dianhydride (PMDA) as monomer source materials are used and polymerized in a chamber.

Because PMDA is likely to be sublimated, although PMDA is a solid source material, a film deposition apparatus of the polyimide is provided with a PMDA evaporator.

The PMDA evaporator generates a source gas by heating a source tank containing a solid source material, the interior of which is kept under vacuum. Especially, as a method of sublimating an organic compound having a sublimation property such as PMDA, a method of using carriers such as beads having the organic compound on their surfaces, which are supplied into a sublimation container, has been disclosed (see Patent Document 1, for example).

Patent Document 1: Japanese translation of PCT International Application No. 2005-535112

### SUMMARY OF INVENTION

### Problems to be Solved by the Invention

When the polyimide film is used as an insulation layer of semiconductor devices, it is required that the polyimide film has great density and high adhesiveness. To this end, when depositing the polyimide film, the evaporated PMDA needs to be continuously supplied at a constant flow rate. However, when PMDA gas (or vapor) obtained by heating to sublimate the solid PMDA in a sublimation container is supplied to a chamber, because an amount of the solid PMDA is reduced through sublimation and thus a surface area of the solid PMDA is reduced, it is difficult to continuously supply the PMDA gas at a constant amount to the chamber.

In the method described in Patent Document 1 to sublimate the organic compound, the organic compound that covers the carrier surfaces is heated through a heat medium such as a carrier gas. Because the organic compound has a large surface area, a sufficient amount of evaporated gas can be obtained. However, as the organic compound is being sublimated, a surface area of the organic compound is decreased, which makes it impossible to continuously and stably supply the evaporated organic compound at a constant flow rate to the chamber.

In addition, when the sublimation container is re-filled with the organic compound, the film deposition apparatus with the sublimation container needs to be brought to a halt according to the method of Patent Document 1, which makes it difficult to continuously supply the sublimated organic compound to the chamber.

The present invention provides an evaporator that is capable of continuously and stably supplying a source gas obtained by sublimating a solid source material.

### Means of Solving the Problems

A first aspect of the present invention provides an evaporator that sublimates a solid source material to generate a source gas to be supplied to a film deposition apparatus. The evaporator includes a heating part that heats and sublimates the solid source material to generate the source gas; a supplying part that is provided above the heating part and supplies the solid source material to the heating part; a gas introduction part to which a carrier gas that transports the source gas generated in the heating part is introduced; and a gas discharging part that discharges the generated source gas along with the carrier gas. The carrier gas introduced from the gas introduction part flows through the heating part.

A second aspect of the present invention provides an evaporator that sublimates a solid source material to generate a source gas to be supplied to a film deposition apparatus. The evaporator includes a heating part that heats and sublimates the solid source material to generate the source gas; a supplying part that is provided above the heating part and supplies the solid source material to the heating part; and a gas passage provided between the gas introduction part and the gas discharging part, the gas passage being provided below the heating part. The heating part includes a mesh part, and the carrier gas that flows through the gas passage contacts the solid source material via the mesh part.

### BRIEF DESCRIPTION OF THE DRAWINGS

FIG. 1 is a vertical cross-sectional view schematically illustrating an evaporator according to a first embodiment of the present invention.

FIG. 2 is a horizontal cross-sectional view schematically illustrating the evaporator according to the first embodiment of the present invention.

FIG. 3 is an explanatory view for explaining effects (or advantages) of the evaporator according to the first embodiment of the present invention.

FIG. 4 is a vertical cross-sectional view schematically illustrating an evaporator according to a first modified example of the first embodiment of the present invention.

FIG. 5 is a horizontal cross-sectional view schematically illustrating the evaporator according to the first modified example of the first embodiment of the present invention.

FIG. 6 is a vertical cross-sectional view schematically illustrating an evaporator according to a second modified example of the first embodiment of the present invention.

FIG. 7 is an explanatory view for explaining effects (or advantages) of the evaporator according to the second modified example of the first embodiment of the present invention.

FIG. 8 is a cross-sectional view schematically illustrating a film deposition apparatus according to a second embodiment of the present invention.

### MODE(S) FOR CARRYING OUT THE INVENTION

According to embodiments of the present invention, there is provided an evaporator that is capable of continuously and stably supplying a source gas obtained by sublimating a solid source material. In the following, non-limiting embodiments of the present invention will now be described with reference to the accompanying drawings. In the drawings, the same or corresponding reference symbols are given to the same or corresponding members or components, and repetitive explanations may be omitted.

### First Embodiment

An evaporator according to a first embodiment of the present invention is to supply an evaporated PMDA to an apparatus for depositing a polyimide film through vapor deposition polymerization using ODA and PMDA as a source monomer.

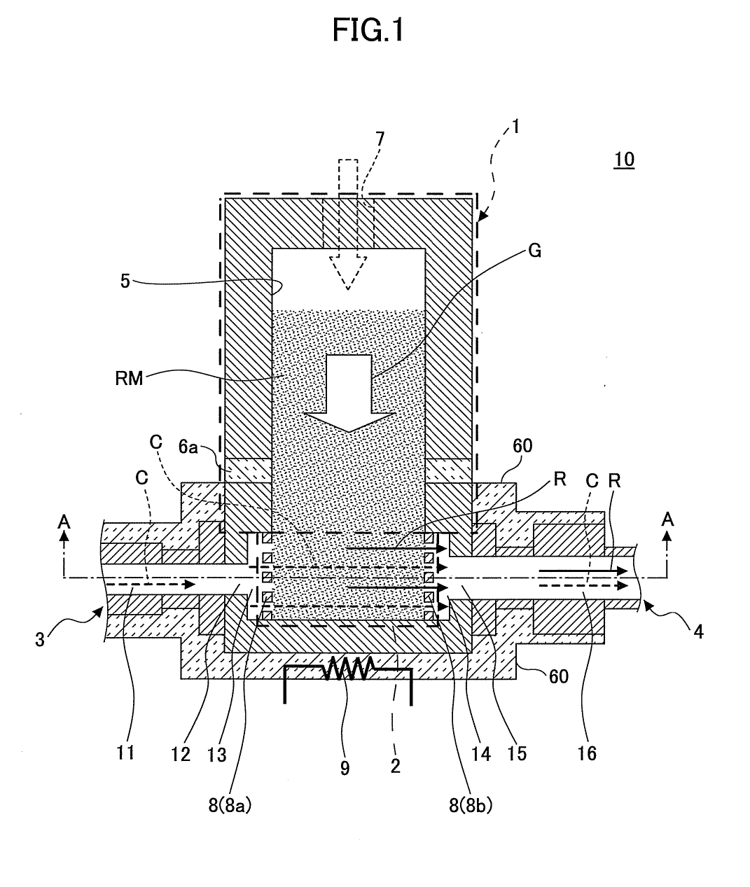

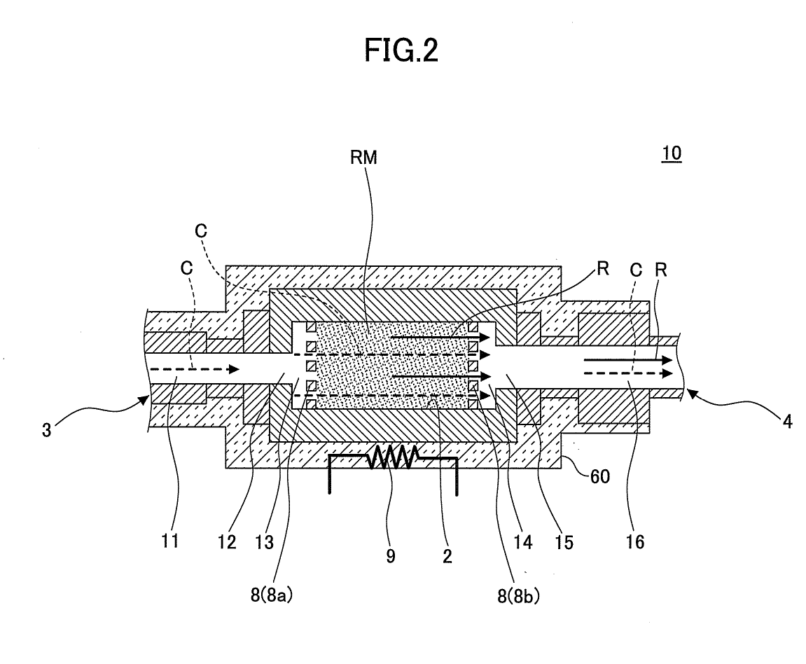

FIG. 1 is a vertical cross-sectional view illustrating the evaporator according to this embodiment. FIG. 2 is a cross-sectional view taken along A-A line of FIG. 1.

As shown in FIG. 1, an evaporator 10 according to this embodiment is composed of a supplying part 1, a heating part 2, a gas introduction part 3, and a gas discharging part 4.

The supplying part 1 includes a source material storage part 5, a thermal insulation member 6a, and a source material introduction opening 7 that is closable and arranged above the source material storage part 5. In the supplying part 1 including the source material storage part 5, which may be referred to as the supplying part 1 (source material storage part 5), including the thermal insulation member 6a and the source material introduction opening 7, even when mainly the source material storage part 5 is meant, hereinafter, a powder source material RM of PMDA (referred to as a PMDA powder) is stored. The supplying part 1 supplies the PMDA powder RM stored in the source material storage part 5 to the heating part 2. The heating part 2 holds the PMDA powder RM supplied from the supplying part 1 and heats to sublimate the PMDA powder RM, thereby producing PMDA gas R. Carrier gas C is introduced from the gas introduction part 3 into the heating part 2. In addition, the PMDA gas R generated in the heating part 2 is discharged from the gas discharging part 4.

The supplying part 1 has a volume that allows a sufficient amount of the PMDA powder RM to be stored, as shown in FIG. 1, and has the source material introduction opening 7 that allows the PMDA powder RM to be easily supplied into the source material storage part 5. A lower portion of the supplying part 1 (source material storage part 5) is in physical communication with the heating part 2. With this, the PMDA powder RM stored in the supplying part 1 (source material storage part 5) from the source material introduction opening 7 falls under its own weight due to gravitational force G and thus is supplied to the heating part 2.

A volume of the supplying part 1 (source material storage part 5) may be greater than a volume of the heating part 2. To this end, a height of the supplying part 1 (source material storage part 5) may be greater than a height of the heating part 2, for example, as shown in FIG. 1.

In addition, a part of a side wall of the supplying part 1 (source material storage part 5) is preferably made of the thermal insulation member 6a. This is because an amount of heat propagating from the heating part 2, which is arranged below the supplying part 1, toward a central part and an upper part of the supplying part 1 can be further reduced.

In this embodiment, the heating portion 2 has a container-like shape that has an open upper end and two opposing side surfaces made of mesh parts 8 (a first mesh part 8a, a second mesh part 8b). The mesh parts 8 are capable of keeping the PMDA powder RM within the heating part 2 and allows gaseous communication between an inside and an outside of the heating part 2. The mesh part 8 may be made of a metal mesh such as a stainless steel mesh.

When an average particle size of the PMDA powder falls within a range from 200 μm through 300 μm, the PMDA powder may include about 1% of PMDA particles having a particle size of 100 μm or less. When the PMDA powder having such particle size distribution is used, an average mesh opening size of the mesh parts 8 may be about 100 μm. Namely, the mesh parts 8 preferably have an opening size smaller than or equal to the average particle size of the source material powder. More preferably, the mesh parts 8 have an opening size smaller than or equal to a particle size of a source material powder whose content percentage is about 1% or less in the particle size distribution.

The open upper surface of the heating part 2 is in physical communication with the supplying part 1 (source material storing part 5), so that the PMDA powder RM stored in the supplying part 1 (source material storing part 5) falls due to the gravitational force G, and is held by the heating part 2. Therefore, even when the PMDA powders RM are consumed through sublimation to generate voids in the PMDA powders, the PMDA powders RM fall into the voids from the supplying part 1 (source material storing part 5), thereby filling the voids.

In this embodiment, a heating mechanism 9 is provided in a lower portion of the heating part 2 serving as a heat source of the heating part 2. The heating mechanism 9 includes, for example, a heating wire, which heats the PMDA powder stored in the heating part 2. In addition, the heating part 2, the gas introduction part 3, the gas discharging part 4, and the lower part of the supplying part 1 are surrounded by a thermal insulation member 60, which reduces heat dissipation toward an exterior. Therefore, the PMDA powder is efficiently heated by the heating mechanism 9.

Incidentally, as long as the PMDA powder stored in the heating part 2 can be heated, the heating mechanism 9 may be arbitrarily arranged.

The gas introduction part 3 includes a gas introduction pipe 11, a gas introduction opening 12, and a gas introduction chamber 13. The gas introduction chamber 13 is partitioned from the heating part 2 by the first mesh part 8a of the heating part 2. The gas introduction pipe 11 is connected at the gas introduction opening 12 to the gas introduction chamber 13 in order to introduce the carrier gas C that carries the PMDA gas R to the heating part 2.

The gas discharging part 4 includes a gas discharging chamber 14, a gas discharging opening 15, and a gas discharging pipe 16. The gas discharging chamber 14 is partitioned from the heating part 2 by the second mesh part 8b of the heating part 2, and arranged on the other side of the gas introduction chamber 13 with the heating part 2 therebetween. The gas discharging pipe 16 is connected at the gas discharging opening 15 to the gas discharging chamber 14 in order to guide the carrier gas that is carrying the PMDA gas R from the evaporator 10 to a film deposition apparatus (not shown).

With such a configuration, the carrier gas C flows through the gas introduction part 3, the heating part 2, and the gas discharging part 4 in this order. Therefore, the carrier gas C flows substantially exclusively through the heating part 2 arranged below the supplying part 1 (source material storage part 5), and rarely flows into the supplying part 1 (source material storage part 5) to contact the PMDA powder stored in the supplying part 1 (source material storage part 5). In addition, a flow direction of the carrier gas C is orthogonal to a direction along which the PMDA powder stored in the supplying part 1 (source material storage part 5) is supplied to the heating part 2, in this embodiment.

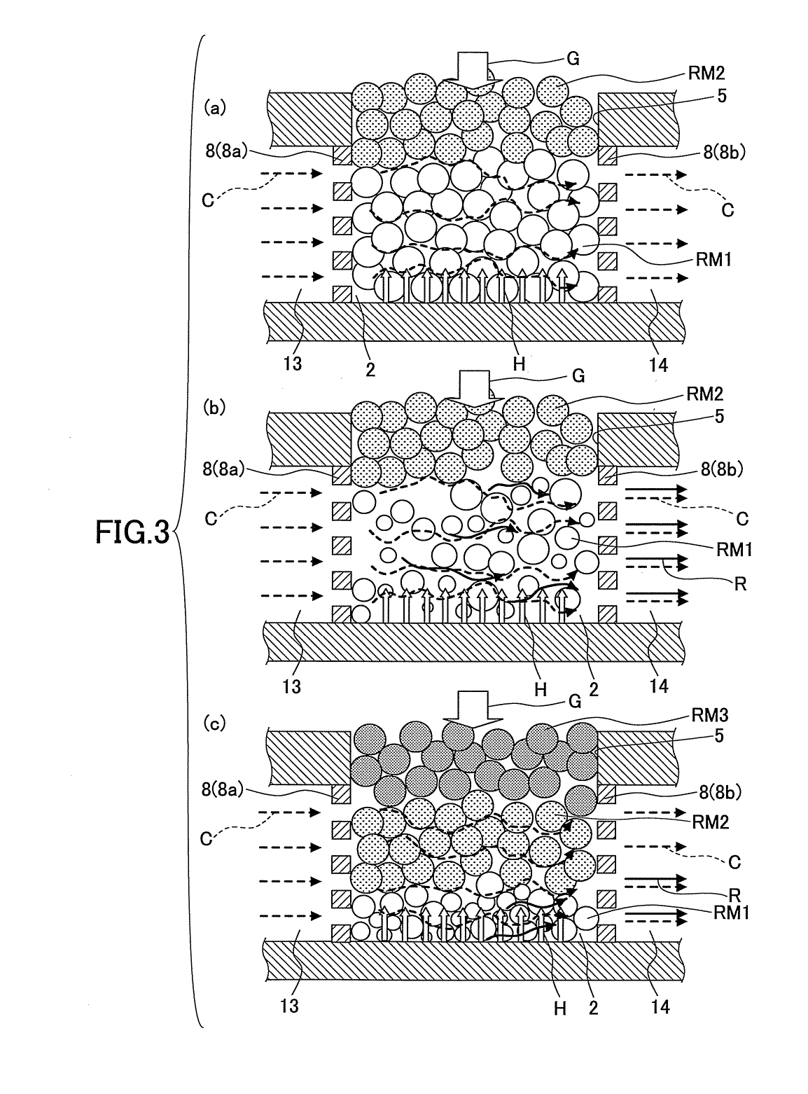

Next, effects (or advantages) of the evaporator 10 according to this embodiment are explained with reference to FIGS. 1 and 3. FIG. 3 schematically illustrates the PMDA powder in the heating part 2.

A subsection (a) of FIG. 3 schematically illustrates PMDA powder RM1 when the PMDA powder RM1 stored in the heating part 2 starts to be heated. Incidentally, the heating mechanism 9 is omitted in FIG. 3.

As shown, the carrier gas C flows into the heating part 2 from the gas introduction chamber 13 through the first mesh part 8a, and flows out from the heating part 2 to the gas discharging chamber 14 through the second mesh part 8b. In this situation, when the heating mechanism 9 (FIGS. 1 and 2) is turned ON, heat H generated by the heating mechanism 9 propagates throughout a bottom surface portion and side surfaces including the mesh part 8 of the heating part 2, and thus the PMDA powder stored in the heating part 2 starts to be heated.

When the PMDA powder RM1 stored in the heating part 2 is heated up to a temperature exceeding the sublimation temperature of PMDA, and maintained at the temperature, the PMDA powder RM1 is sublimated to produce the PMDA gas R, as shown in the subsections of FIG. 3. The PMDA gas R is carried by the carrier gas C to flow out to the gas discharging chamber 14 from the heating part 2 through the second mesh part 8b. Then, the carrier gas C including the PMDA gas is supplied to the film deposition chamber.

Incidentally, the first mesh part 8a and the second mesh part 8b are entirely arranged to be the opposing side surfaces of the heating part 2 in this embodiment as shown in FIG. 2, and an almost entire part of the PMDA powder RM1 stored in the heating part 2 can contact the carrier gas C. Therefore, the PMDA gas can be efficiently carried by the carrier gas C. As a result, the sublimation reaction of the PMDA powder RM1 is facilitated, thereby enhancing production efficiency of the PMDA gas.

In addition, because PMDA powder RM2 stored in the supplying part 1 (source material storage part 5) in physical communication with the upper portion of the heating part 2 is not heated up to the sublimation temperature of PMDA, the PMDA powder RM 2 is rarely sublimated to produce the PMDA gas R. In other words, the PMDA powder RM1 stored in the heating part 2 is heated in this embodiment.

Incidentally, PMDA powder stored in and around the boundary between the heating part 2 and the supplying part 1 (source material storage part 5) may be heated up to a temperature higher than the sublimation temperature due to thermal propagation of the heat H from the heating part and thus may be sublimated. However, the PMDA gas is generated only from the PMDA powder stored near the boundary, and not generated from the entire PMDA powder stored in the supplying part 1 (source material storage part 5).

As the PMDA gas R is being generated in the heating part 2 as described above, the particle size of the PMDA powder RM1 becomes smaller, and thus voids may be produced within the PMDA powder RM1 stored in the heating part 2, as shown in a subsection (b) of FIG. 3.

However, the voids are readily filled because the PMDA powder RM2 stored in the supplying part 1 (source material storage part 5) falls due to the gravitational force G, as shown in a subsection (c) of FIG. 3. When the voids are generated, a total surface area of the PMDA powder RM1 becomes less, and thus an amount of the generated PMDA gas R is reduced. According to this embodiment, such voids can be filled, which makes it possible to produce the PMDA gas R at a constant rate over a relatively long period of time. In addition, PMDA powder RM3 stored in the central or the upper portion of the supplying part 1 (source material storage part 5) falls to the lower portion of the supplying part 1 (source material storage part 5) due to the gravitational force G. In such a manner, because the heating part 2 is re-filled by the PMDA powders RM2, RM3 that are stored the supplying part 1 (source material storage part 5) and fall downward due to the gravitational force G, production of the PMDA gas R is maintained.

Incidentally, while the subsection (c) of FIG. 3 illustrates the voids of the PMDA powder RM1 generated because the PMDA gas R is generated in the heating part 2, only a tiny void can be readily filled by the PMDA powder RM2 from the supplying part 1 (source material storage part 5) in reality. Therefore, a situation illustrated in the subsection (c) of FIG. 3 is substantially maintained. Namely, because an amount of the PMDA powder RM1 in the heating part 2 can be maintained constant in the evaporator 10 according to this embodiment, an amount of the generated PMDA gas can be maintained constant.

In addition, because the volume of the supplying part 1 (source material storage part 5) is greater than the volume of the heating part 2, when a sufficient amount of the PMDA powder is stored in the supplying part 1 (source material storage part 5), the PMDA gas can be supplied to a chamber for a relatively long period of time without resupplying the PMDA powder RM.

In addition, even when a certain period of time has elapsed and a remaining amount of the PMDA powder RM is decreasing, the PMDA powder RM can be supplied from the source material introduction opening 7 during the production of the PMDA gas, because the source material introduction opening 7 is away from the heating part 2 and sublimation of the PMDA powder RM1 is not affected even if the source material introduction opening 7 is opened.

### First Modified Example of First Embodiment

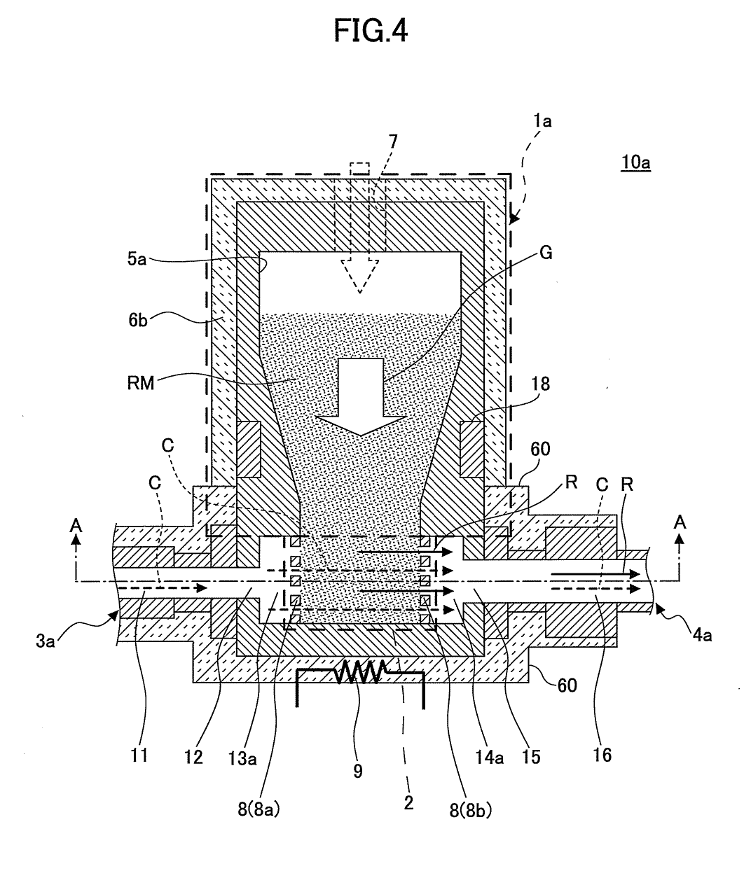

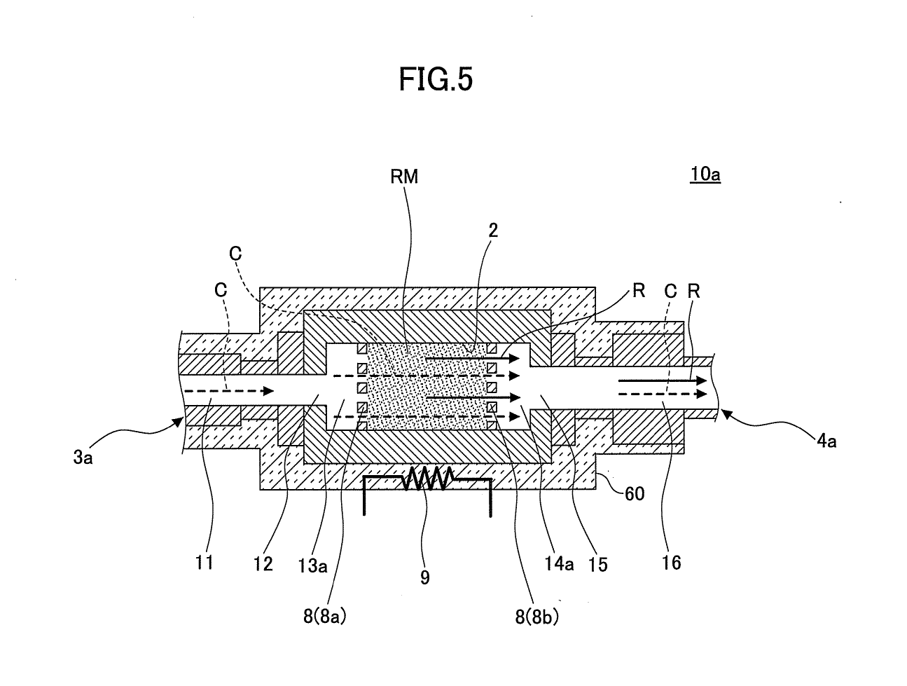

Next, a first modified example of the first embodiment is explained with reference to FIGS. 4 and 5.

FIG. 4 is a vertical cross-sectional view schematically illustrating an evaporator according to this modified example. FIG. 5 is a cross-sectional view taken along A-A line of FIG. 4.

The evaporator according to this modified example is different from the evaporator 10 according to the first embodiment mainly in terms of shapes of the supplying part (source material storage part) and the heating part, and the rest is substantially the same as the evaporator 10. The following explanation is focused on the differences.

Referring to FIG. 4, in an evaporator 10a according to this modified example, a supplying part 1a (source material storage part 5a) has not only a height greater than the height of the heating part 2 but also a cross-sectional area greater than the cross-sectional area of the heating part 2. For example, the supplying part 1a (source material storage part 5a) has in its upper portion a cross-sectional area greater than the cross-sectional area of the heating part 2. In addition, side surfaces of the supplying part 1a (source material storage part 5a) are slanted, and thus the supplying part 1a (source material storage part 5a) has a shape whose cross-sectional area is gradually decreasing from above to below. With this, the supplying part 1a (source material storage part 5a) has a sufficiently larger volume than the volume of the heating part 2. Therefore, once a sufficient amount of the PMDA powder is supplied in the supplying part 1a (source material storage part 5a), a constant amount of the PMDA gas can be supplied to the film deposition apparatus for a relatively long period of time.

In addition, when the cross-sectional area is decreased from above to below, a higher pressure is applied to a lower portion, compared with a case where the cross section is constant in a vertical direction. Therefore, the PMDA powder can be efficiently supplied from the supplying part 1a (source material storage part 5a) to the heating part 2.

Additionally, the cross-sectional area of the heating part 2 may be relatively smaller in order to make the cross-sectional area of the supplying part 1a (source material storage part 5c) relatively larger than the cross-sectional area of the heating part 2. With this, the PMDA powder held in the heating part 2 can be maintained at a more constant temperature. Therefore, because the PMDA gas is generated from the entire PMDA powder amount in the heating part 2 and thus the PMDA powder uniformly disappears, the PMDA powder is uniformly supplied to the entire heating part 2 from the supplying part 1a (source material storage part 5a).

Moreover, when the cross-sectional area of the heating part 2 becomes small, the gas introduction chamber 13a can be made larger as shown in FIGS. 4 and 5. With this, because the carrier gas C can uniformly flow through the mesh part 8a to be introduced into the heating part 2, the PMDA powder in the heating part 2 may uniformly disappear. Furthermore, the gas discharging chamber 14a can be also made larger by decreasing the cross-sectional area of the heating part 2, thereby facilitating the carrier gas C to uniformly flow through the heating part 2.

In addition, while a part of the side wall of the source material storage part 5 is composed of the thermal insulation member 6a in the first embodiment, a thermal insulation member 6b may be provided in order to surround the source material storage part 5a.

Moreover, the evaporator 10a of this modified example is provided with a vibration mechanism 18 that vibrates the supplying part 1a (source material storage part 5a). With this, the PMDA powder is facilitated to fall down to the heating part 2 from the supplying part 1a (source material storage part 5a), and thus an amount of the PMDA gas generated in the evaporator 10a may be further stabilized. The vibration mechanism 18 may include, for example, a piezoelectric vibration element. In this case, when a vibration frequency is adjusted by adjusting a frequency of a driving voltage of the piezoelectric vibration element, the PMDA powder can be further facilitated to fall down.

### Second Modified Example of First Embodiment

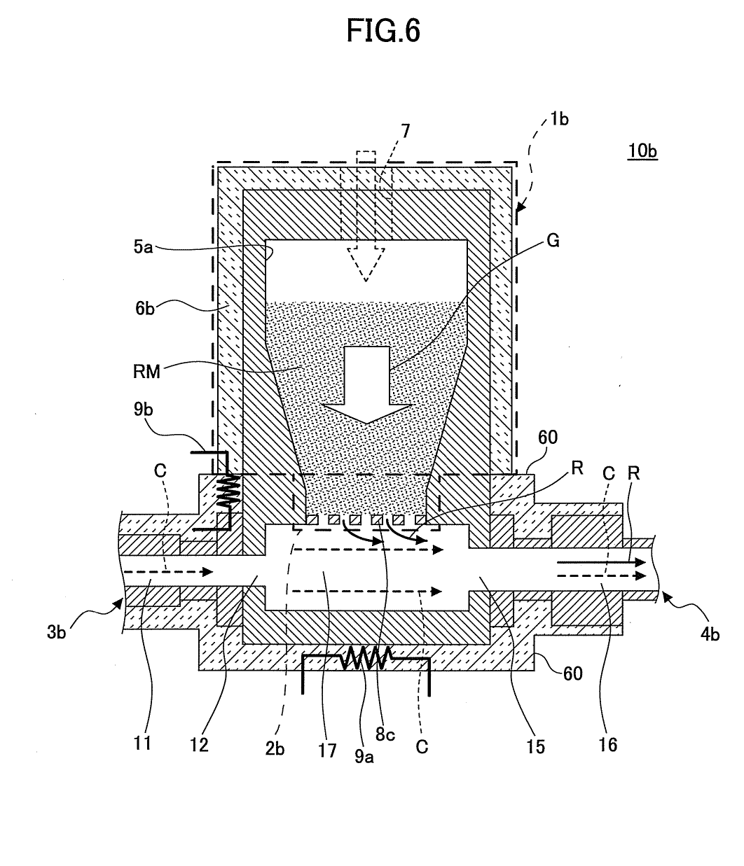

Next, a second modified example of the first embodiment according to the present invention is explained with reference to FIG. 6.

An evaporator according to this modified example is different from the evaporator 10a according to the first modified example of the first embodiment in that the evaporator of this modified example has a gas passage through which the carrier gas flows in a lower portion of the heating part, and the rest is substantially the same as the evaporator 10a. The following explanation is focused on the differences.

Referring to FIG. 6, a heating part 2b has a container-like shape of a parallelepiped that includes an open upper end and a bottom surface made of a mesh part 8c. The mesh part 8c holds the PMDA powder in the heating part 2b, and allows gas to flow between the inside and the outside of the heating part 2b. The mesh part 8c is made of a mesh of a metal such as stainless steel, in the same manner as the mesh parts 8a, 8b in the first embodiment and its first modified example.

A gas passage 17 is provided in a lower portion of the heating part 2b. The gas passage 17 connects the gas introduction part 3b and the gas discharging part 4b in order to be in gaseous communication with each other. With this, the carrier gas C flows through the gas introduction pipe 11, the gas introduction opening 12, the gas passage 17, the gas discharging opening 15, and the gas discharging pipe 16 in this order.

Incidentally, portions corresponding to the gas introduction part 3 (or 3a) and the gas introduction chamber 13 (or 13a) in the first embodiment (or its first modified example) are included in the gas passage 17.

In addition, the evaporator 11b according to this modified example is provided with a heating mechanism 9a that heats the heating part 2b via the gas passage 17 in a lower portion of the heating part 2b, and a heating mechanism 9b that heats the heating part 2b from its side.

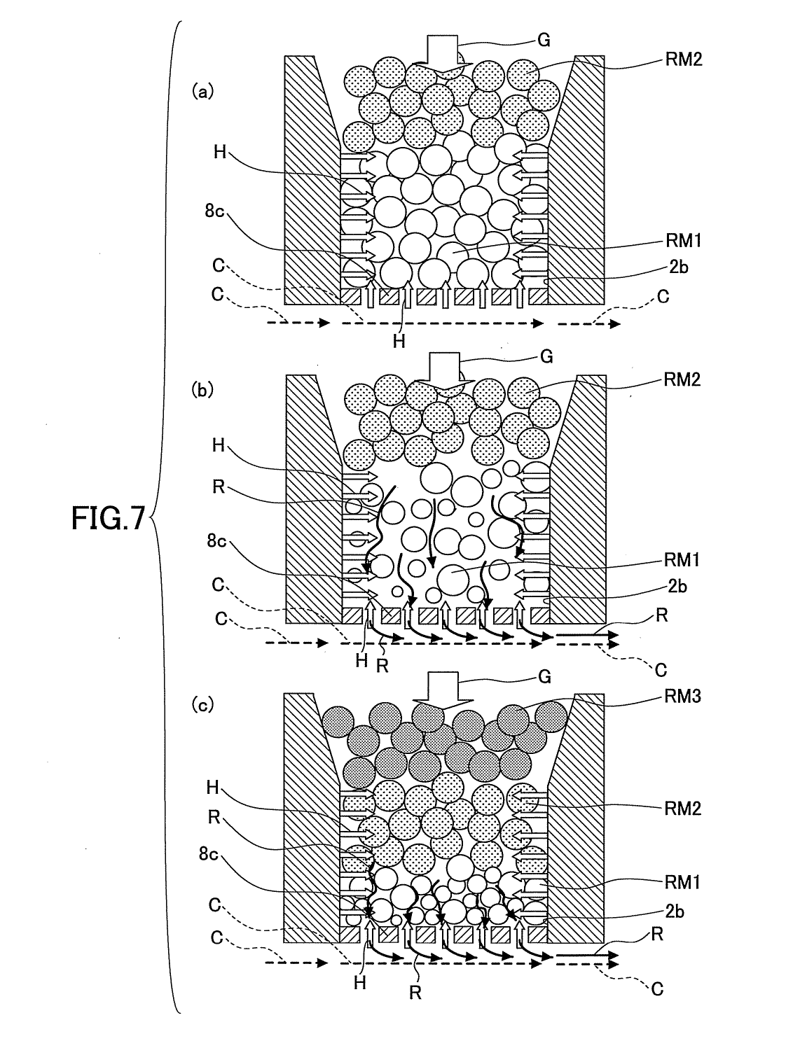

Next, effects (or advantages) of the evaporator 10b according to this embodiment are explained with reference to FIG. 7. FIG. 7 schematically illustrates the PMDA powder in the heating part 2b.

As shown in a subsection (a) of FIG. 7, the carrier gas C flows through the gas passage 17, and comes in contact with the PMDA powder RM1 held in the heating part 2b via the mesh part 8c. In this situation, when the heating mechanisms 9a, 9b are turned ON, the PMDA powder RM1 held by the heating part 2b starts to be heated by the heating mechanisms 9a, 9b.

When the PMDA powder RM1 held by the heating part 2b is heated up to the PMDA sublimation temperature or more, the PMDA powder RM1 is sublimated and thus the PMDA gas R is generated, as shown in a subsection (b) of FIG. 7. The PMDA gas R is guided by the carrier gas C flowing through the gas passage 17 to flow out to the gas passage 17 through the mesh part 8c. Then, the PMDA gas is transported by the carrier gas C to reach a chamber of a film deposition apparatus from the gas discharging pipe 16 (FIG. 6). On the other hand, because the PMDA powder RM2 or the like stored in the supplying part 1b (source material storage part 5a) is rarely heated to the sublimation temperature, the PMDA gas is rarely generated from the PMDA powder RM2 or the like.

Incidentally, the PMDA powder stored near the boundary between the supplying part 1b (source material storage part 5b) and the heating part 2b is heated at temperatures higher than the sublimation temperature by thermal conduction of the heat H from the heating part 2b, and thus is sublimated. However, the PMDA gas is generated only from the PMDA powder stored near the boundary, and not generated from the entire PMDA powder amount stored in the supplying part 1b (source material storage part 5b).

As the PMDA gas R is being generated in the heating part 2b as described above, the particle size of the PMDA powder RM1 becomes smaller, and thus voids may be produced within the PMDA powder PM1 stored in the heating part 2b, as shown in a subsection (b) of FIG. 7.

However, the voids are readily filled because the PMDA powder RM2 stored in the supplying part 1b (source material storage part 5b) falls due to the gravitational force G, as shown in a subsection (c) of FIG. 7. Therefore, the evaporator 10b according to the second modified example of the first embodiment can provide the same effects as the evaporators 10 and 10a according to the first embodiment and its first modified example.

### Second Embodiment

Next, a film deposition apparatus according to a second embodiment of the present invention is explained. The film deposition apparatus according to this embodiment is an apparatus that deposits an insulation film on a wafer surface using the PMDA gas supplied from the evaporator according to the first embodiment of the present invention.

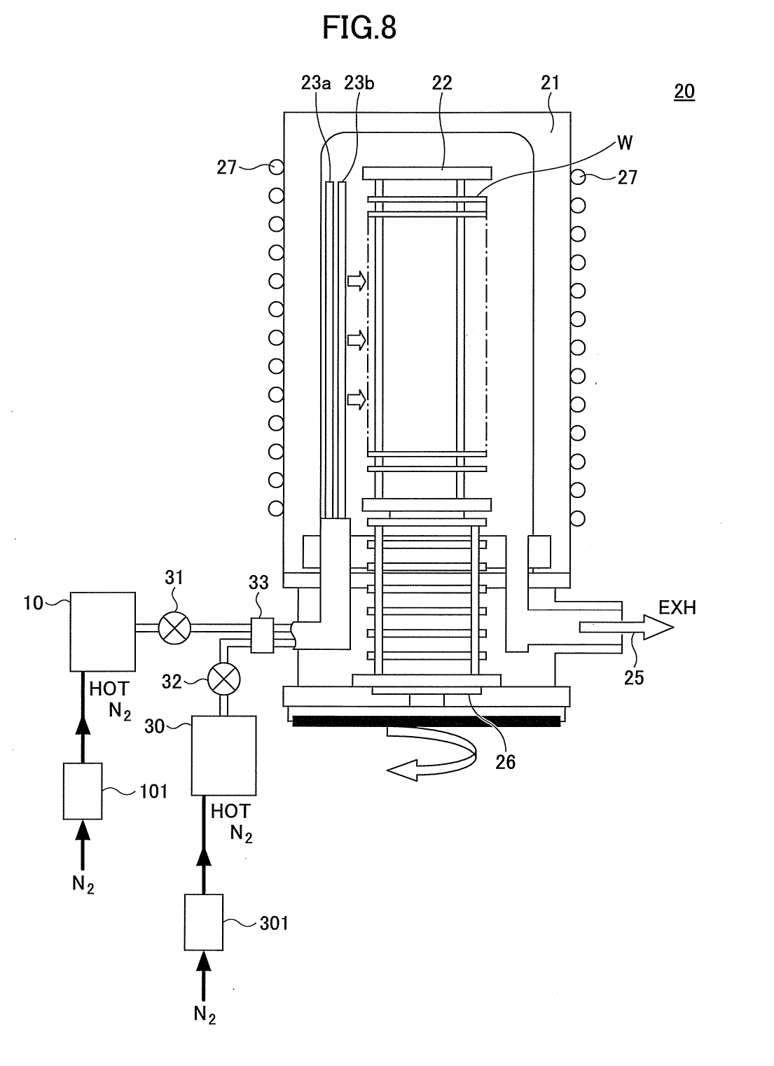

FIG. 8 is a cross-sectional view illustrating the film deposition apparatus according to this embodiment. As shown in FIG. 8, a film deposition apparatus 20 includes a wafer boat 22 that is capable of holding plural wafers W on which polyimide films are deposited, in a chamber 21 that can be evacuated by a vacuum pump (not shown) or the like. In addition, injectors 23a, 23b for supplying the evaporated PMDA and ODA are provided in the chamber 21. The injectors 23a, 23b have openings on their side surfaces, and the PMDA and ODA evaporated by the evaporator are supplied to the wafers W through the openings, as shown by arrows in the drawing. The supplied PMDA and ODA are reacted through vapor deposition polymerization and thus the polyimide film is deposited on the wafers W. Incidentally, the evaporated PMDA and ODA that do not contribute to film deposition of the polyimide film flow through and are evacuated out of the chamber 21 from an evacuation port 25. In addition, the wafer boat 22 is configured to be rotatable so that the polyimide films are uniformly deposited on the wafers W. Moreover, a heater 27 is provided outside the chamber 21 in order to heat the wafers W in the chamber 21 at a given temperature.

In addition, an ODA evaporator 30 and a PMDA evaporator 10 according to the first embodiment are connected to the injectors 23a and 23b respectively through corresponding valves 32 and 31, and through an introduction part 33. Incidentally, although the evaporator 10 according to the first embodiment is used as the PMDA evaporator in the second embodiment, one of the evaporators 10a and 10b according to the first and the second modified examples of the first embodiment, respectively, may be used.

As shown in FIG. 8, a heating unit 101 that heats nitrogen gas as a carrier gas is provided to the PMDA evaporator 10, so that the nitrogen gas heated to a temperature higher than a normal temperature (preferably a temperature higher than the sublimation temperature of the PMDA powder) by the heating unit 101 is supplied to the PMDA evaporator 10. With this, the PMDA powder in the PMDA evaporator 10 is certainly maintained at a high temperature (e.g., about 260° C.) without being cooled by the nitrogen gas, and thus the PMDA is efficiently sublimated. In addition, a heating unit 301 that heats nitrogen gas is provided to the ODA evaporator 30, so that the nitrogen gas heated to a temperature higher than the normal temperature is supplied to the ODA evaporator 30. With this, the ODA that is heated to, for example, about 220° C. to be liquid is bubbled by the nitrogen gas without being cooled by the nitrogen gas, and thus the ODA vapor (gas) is supplied by the nitrogen gas to the film deposition apparatus 20.

Subsequently, the evaporated PMDA and the ODA are supplied to the corresponding injectors 23a and 23b through the corresponding valves 31 and 32, and thus deposited on the wafers W. At this time, the polymerization reaction of the PMDA and ODA takes place following the next formula (1).

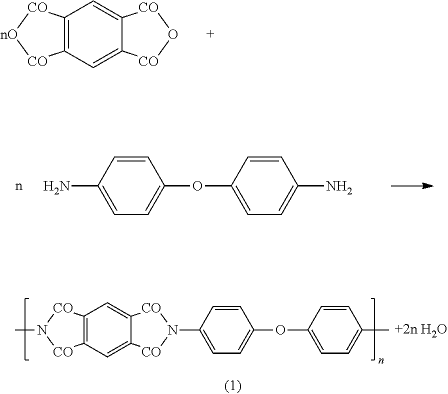

In the foregoing, while preferred embodiments according to the present invention have been described, the present invention is not limited to the specific embodiments, but may be variously modified or altered within the scope of the accompanying Claims.

For example, the vibration mechanism 18 (FIG. 4) provided in the evaporator 10a according to the first modified example of the first embodiment may be the evaporators according to the other embodiments (including the modified examples). In addition, the vibration mechanism 18 may be provided in order to vibrate the heating parts 2, 2b or other portions of the evaporators 10-10b in addition to or instead of vibrating the supplying part 1-1b, as long as the vibration mechanism 18 can facilitate the PMDA powder in the supplying parts 1-1b (source material storage parts 5-5b) falling down to the heating parts 2, 2b.

Moreover, a small amount of, for example, nitrogen gas, inert gas, or the like may be introduced into the supplying parts 1-1b (source material storage parts 5-5b) from the above-mentioned source material introduction opening 7 or a gas introduction opening provided separately from the source material introduction opening 7. By supplying a small amount of the gas to the supplying parts 1-1b (source material storage parts 5-5b), the PMDA gas R generated in the heating parts 2, 2b is impeded from diffusing from the heating parts 2, 2b toward the supplying parts 1-1b (source material storage parts 5-5b) through the PMDA powder PM. Therefore, the PMDA gas R generated in the heating parts 2, 2b can be stably supplied to the film deposition apparatus from the gas discharging parts 4-4b.

A shape of the heating part 2 is not limited to a parallelepiped, but may be cubic. Even in this case, the heating part 2 may have an upper opening and opposing two side surfaces as the mesh parts 8. In addition, the heating part 2 may have an arbitrary shape, as long as the heating part 2 has an upper opening in order to be in physical communication with the supplying part 1 (source material storage part 5) above the heating part 2 and has the mesh parts 8 that allow the carrier gas C to flow through the heating part 2.

In addition, the mesh part 8c constituting the bottom surface of the heating part 2b in the evaporator 10b according to the second modified example of the first embodiment is not limited to be flat but may be convex downward.

Moreover, a source material transfer pipe may be connected to the source material introduction openings 7, 7a, and the PMDA powder (solid source material) may be introduced into the supplying part 1 (source material storage part 5) through the source material transfer pipe.

The insulation members 6a, 6b may be made of a material having thermal conductivity less than the thermal conductivity of the material of the heating part 2 having a container-like shape. With this, the PMDA powder stored in the supplying part 1 (source material storage part 5) is further impeded from being heated above the sublimation temperature.

In addition, the gas introduction chamber 13, the heating part 2, and the gas discharging chamber 14 may be continuously integrated in the gas introduction part 3, as long as the carrier gas C can be introduced into the heating part 2.

Incidentally, while the boundary between the heating part 2 and the supplying part 1 (or 1a) can be relatively easily defined because the carrier gas flows through the heating part 2 in the evaporator 10 (or 10a) according to the first embodiment (or its first modified example), the boundary between the heating part 2b and the supplying part 1b is not easily defined. However, the heating part 2b that heats and sublimates the PMDA powder and the supplying part 1b that is arranged above the heating part 2b and is capable of supplying the PMDA powder to the heating part 2b are defined.

In addition, the supplying parts 1, 1a, 1b and the heating parts 2, 2b are provided in one container and the PMDA powder is supplied into the heating parts 2, 2b from the supplying parts 1, 1a, 1b due to its own weight. However, the supplying parts 1, 1a, 1b and the heating parts 2, 2b may be configured as separate bodies, as long as the PMDA powder can be supplied to the heating parts 2, 2b from the supplying parts 1, 1a, 1b.

Moreover, while the PMDA powder is sublimated to generate the PMDA gas in the above explanation, other solid source materials can be apparently used in other embodiments.

This international application claims priority based on Japanese Patent Application No. 2009-061587 filed Mar. 13, 2009, the entire content of which is incorporated herein by reference in this international application.

1. An evaporator that sublimates a solid source material to generate a source gas to be supplied to a film deposition apparatus, the evaporator comprising:
a heating part that heats and sublimates the solid source material to generate the source gas;
a supplying part that is provided above the heating part and supplies the solid source material to the heating part;
a gas introduction part to which a carrier gas that transports the source gas generated in the heating part is introduced; and
a gas discharging part that discharges the generated source gas along with the carrier gas.

2. The evaporator as recited in claim 1, wherein the heating part, the gas introduction part, and the gas discharging part are arranged so that the carrier gas introduced from the gas introduction part flows through the heating part and is discharged from the gas discharging part.

3. The evaporator as recited in claim 2, wherein the heating part comprises a mesh part that is capable of maintaining the solid source material and has an aeration property, wherein the carrier gas goes through the mesh part when flowing through the heating part.

4. The evaporator as recited in claim 1, further comprising a gas passage provided between the gas introduction part and the gas discharging part, wherein the heating part is provided so that a mesh part that is capable of maintaining the solid source material and has an aeration property is exposed to the gas passage.

5. The evaporator as recited in claim 1, wherein the solid source material is heated in the heating part.

6. The evaporator as recited in claim 3, wherein a mesh opening size of the mesh part is smaller than a particle size of a source powder of the solid source material.

7. The evaporator as recited in claim 4, wherein a mesh opening size of the mesh part is smaller than a particle size of a source powder of the solid source material.

8. The evaporator as recited in claim 1, further comprising a carrier gas heating unit that heats the carrier gas to be introduced from the gas introduction part to the heating part.

9. The evaporator as recited in claim 1, wherein a heating temperature of the carrier gas in a carrier gas heating unit is higher than a sublimation temperature of the solid source material.

10. The evaporator as recited in claim 1, further comprising a vibration mechanism provided so that the solid source material in the supplying part may be vibrated.
